(19) United States
(12) Patent Application Publication
(10) Pub. No.: US 2006/0068100 A1
(43) Pub. Date: Mar. 30, 2006

(54) Film forming method

(75) Inventors: Hideaki Machida, Yamanashi (JP); Yoshio Ohshita, Aichi (JP); Atsushi Ogura, Tokyo (JP); Masato Ishikawa, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Tri Chemical Laboratories Inc., Kitatsuru-gun (JP)

(21) Appl. No.: 11/141,002

(22) Filed: Jun. 1, 2005

(30) Foreign Application Priority Data
Sep. 30, 2004 (JP) 2004-285720

(51) Int. Cl. C23C 16/00

(52) U.S. Cl. 427/248.1

(57) ABSTRACT

A technique is provided that is capable of employing raw materials having no halogen, which has a high possibility of exerting a bad influence upon semiconductor elements, thereby to easily form molybdenum films (molybdenum silicide films or molybdenum nitride films) of which purity is high at a low temperature. A film forming material for forming molybdenum films, molybdenum silicide films, or tungsten nitride films is provided, wherein a Mo source of said film is one or more chemical compounds selected from the group consisting of a biscyclopentadienylmolybdenum dihydride, a bismethylcyclopentadienylmolybdenum dihydride, a bisethylcyclopentadienylmolybdenum dihydride, and a bisisopropylcyclopentadienylmolybdenum dihydride.

### BACKGROUND OF THE INVENTION

The present invention relates to a forming method and a forming material of molybdenum films (or molybdenum silicide films, or molybdenum nitride films). Further, the present invention relates to a film formed by employing said material. Also, the present invention relates to elements such as semiconductor elements comprising said films.

At the present moment, the progress in the semiconductor fields is remarkable, and LSIs are being converted into ULSIs. And, so as to improve a signal processing speed, forming a fine-grained structure is being developed. Also, copper having a low resistance is selected as wiring conductor materials, and the spacing between wiring conductors is filled with materials having a very low dielectric constant. Moreover, a trend of extremely thinning a film goes up steadily. A conversion of a gate oxide film, which is currently made of SiO₂, into a metal oxide film such as HfO₂ has been also studied.

By the way, the resistance of the gate electrode also has been perceived as problems. Accordingly, it has been long wanted to develop new materials.

In order to overcome such problems, it has been studied to configure the gate electrode of molybdenum (Mo), being conductive metal.

[Patent document 1] JP-P2002-9298A

[Patent document 2] JP-P2002-353458A

[Patent document 3] JP-P2003-258121A

[Patent document 4] JP-P2004-31484A

[Patent document 5] JP-P2004-207481A

By the way, the Mo thin film can be easily formed with a sputtering technique.

However, employing the sputtering to form a film of the gate electrode causes the semiconductor elements to be damaged physically.

For that reason, formation of the molybdenum thin films (wiring conductor films) with a chemical vapor deposition (CVD) process was intended in the semiconductor fields. That is, formation of the molybdenum thin film with the CVD process employing MoCl₅ was intended.

However, there is anxiety that Cl to be contained in raw materials (MoCl₅) might exert a bad influence.

### SUMMARY OF THE INVENTION

Thus, a first problem to be solved by the present invention is to provide a technology of forming molybdenum films (or molybdenum silicide films, or molybdenum nitride films) by employing the CVD process that hardly does a thermal damage to the semiconductor elements.

A second problem to be solved by the present invention is to provide a technology of employing materials having no halogen, which has a high possibility of exerting a bad influence upon the semiconductor elements, thereby to form molybdenum films (or molybdenum silicide films, or molybdenum nitride films).

A third problem to be solved by the present invention is to provide a technology capable of forming molybdenum films (or molybdenum silicide films, or molybdenum nitride films) of which purity is high.

A fourth problem to be solved by the present invention is to provide a technology capable of easily forming molybdenum films (or molybdenum silicide films or molybdenum nitride films) at a low temperature.

In the course of going aggressively with a research for solving the above-mentioned problems, the present inventor et al. noticed that it was very important to specify what should be employed as configuration materials of the molybdenum films (or the molybdenum silicide films, or the molybdenum nitride films).

And, as a result of further having continued the research, it has been found out that a chemical compound represented with the following general formula [I] is very preferably employed as a Mo source. 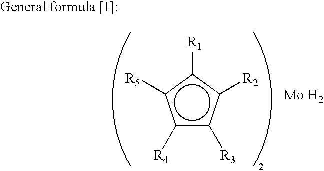
where R₁, R₂, R₃, R₄, or R₅ is H or a hydrocarbon group respectively, each which has the same type or a different type.

Moreover, in addition hereto, it has been also found out that employing chemical compounds represented with SiₓH₍₂ₓ₊₂₎, where X is an integer of 1 or more, allows more preferable silicide films to be produced.

Also, in addition hereto, it has been also found out that employing ammonia allows more preferable nitride films to be produced.

The present invention has been achieved based upon such knowledge.

That is, in order to solve the above-mentioned problems, a method is applied of forming a film containing molybdenum, comprising:
a Mo source supply step of supplying one or more Mo chemical compounds selected from the group of the following general formula [I] as a Mo source of said film; and
a decomposition step of decomposing the Mo chemical compounds supplied in said Mo source supply step. 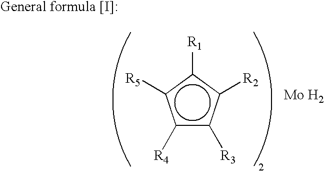
   where R₁, R₂, R₃, R₄, or R₅ is H or a hydrocarbon group respectively, each which has the same type or a different type.

Said Mo chemical compound is, particularly, one or more chemical compounds selected from the group consisting of a biscyclopentadienylmolybdenum dihydride, a bismethylcyclopentadienylmolybdenum dihydride, a bisethylcyclopentadienylmolybdenum dihydride, and a bisisopropylcyclopentadienylmolybdenum dihydride.

The method of the present invention is, particularly, a method of forming a film with a CVD process. And, said decomposition is a decomposition employing at least any one of the techniques selected from the group consisting of heat, light, and a hot filament.

The present invention is particularly employed in a case of forming a gate electrode film.

In particular, the present invention further comprises a reducing agent supply step of supplying a reducing agent (particularly, hydrogen).

In a case where said film is a molybdenum silicide film, the present invention further comprises:
an Si source supply step of supplying SiₓH₍₂ₓ₊₂₎, where X is an integer of 1 or more, as an Si source of said molybdenum silicide film; and
a decomposition step of decomposing the Si chemical compounds supplied in said Si source supply step.

Said Si chemical compound is, particularly, one or more chemical compounds selected from the group consisting of SiH₄, Si₂H₆, and si₃H₈.

Said Mo chemical compound and said Si chemical compound are supplied simultaneously or separately. And, they are decomposed simultaneously or separately.

In a case where said film is a molybdenum nitride film, the present invention further comprises:
an N source supply step of supplying one or more N chemical compounds selected from the group of ammonia and ammonia producing chemical compounds as an N source of said molybdenum nitride film; and
a decomposition step of decomposing the N chemical compounds supplied in said N source supply step.

Said N chemical compound is, particularly, ammonia.

Said Mo chemical compound and said N chemical compound are supplied simultaneously or separately. And, they are decomposed simultaneously or separately.

The present invention provides a film containing molybdenum, said film being obtained through:
a Mo source supply step of supplying one or more Mo chemical compounds selected from the group of the following general formula [I] as a Mo source of said film; and
a decomposition step of decomposing the Mo chemical compounds supplied in said Mo source supply step. 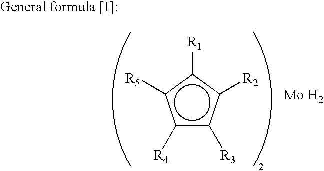
   where R₁, R₂, R₃, R₄, or R₅ is H or a hydrocarbon group respectively, each which has the same type or a different type.

Said Mo chemical compound is, particularly, one or more chemical compounds selected from the group consisting of a biscyclopentadienylmolybdenum dihydride, a bismethylcyclopentadienylmolybdenum dihydride, a bisethylcyclopentadienylmolybdenum dihydride, and a bisisopropylcyclopentadienylmolybdenum dihydride.

The film of the present invention is, particularly, a film formed with a CVD process. Particularly, it is a gate electrode film.

In the present invention, in a case where said film is a molybdenum silicide film, said film is obtained by further going through: an Si source supply step of supplying SiₓH₍₂ₓ₊₂₎, where X is an integer of 1 or more, as an Si source of said molybdenum silicide film; and a decomposition step of decomposing the Si chemical compounds supplied in said Si source supply step.

Said Si chemical compound is, particularly, one or more chemical compounds selected from the group consisting of SiH₄, Si₂H₆, and si₃H₈.

In the present invention, in a case where said film is a molybdenum nitride film, said film is obtained by further going through: an N source supply step of supplying one or more N chemical compounds selected from the group of ammonia and ammonia producing chemical compounds as an N source of said molybdenum nitride film; and a decomposition step of decomposing the N chemical compounds supplied in said N source supply step.

Said N chemical compound is, particularly, ammonia.

Also, the present invention provides a film forming material for forming a film containing molybdenum, wherein a Mo source of said film is one or more Mo chemical compounds selected from the group of the following general formula [I].

In a case where said film is a molybdenum silicide film, the present invention provide a film forming material, wherein a Mo source of said film is one or more Mo chemical compounds selected from the group of the following general formula [I], and wherein an Si source of said film is one or more Si chemical compounds selected from the group consisting of SiₓH₍₂ₓ₊₂₎, where X is an integer of 1 or more.

In a case where said film is a molybdenum nitride film, the present invention provides a film forming material, wherein a Mo source of said film is one or more Mo chemical compounds selected from the group of the following general formula [I], and where an N source of said film is one or more N chemical compounds selected from the group of ammonia and ammonia producing chemical compounds. 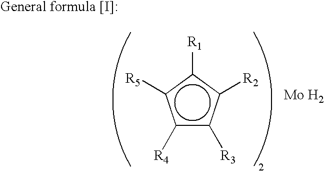
where R₁, R₂, R₃, R₄, or R₅ is H or a hydrocarbon group respectively, each which has the same type or a different type.

Said Mo chemical compound is, particularly, one or more chemical compounds selected from the group consisting of a biscyclopentadienylmolybdenum dihydride, a bismethylcyclopentadienylmolybdenum dihydride, a bisethylcyclopentadienylmolybdenum dihydride, and a bisisopropylcyclopentadienylmolybdenum dihydride.

Said Si chemical compound is, particularly, one or more chemical compounds selected from the group consisting of SiH₄, Si₂H₆, and si₃H₈.

Said N chemical compound is, particularly, ammonia.

The film forming material of the present invention is a material for forming a film with a CVD process. In particularly, it is a material for forming a gate electrode film. In particular, it is a material for forming the gate electrode film in the semiconductor elements such as MOSFETs. Above all, it is a molybdenum silicide film. Or, it is a molybdenum nitride film.

Also, in order to solve the above-mentioned problems, the present invention provides a semiconductor element comprising molybdenum films, molybdenum silicide films, or molybdenum nitride films, wherein one or more Mo chemical compounds selected from the group of the following general formula [I] are supplied as a Mo source, and Mo of said film is configured by decomposing said supplied Mo chemical compounds. 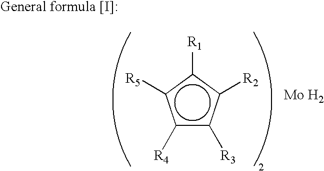
where R₁, R₂, R₃, R₄, or R₅ is H or a hydrocarbon group respectively, each which has the same type or a different type.

In accordance with the present invention, the molybdenum films, the molybdenum silicide films, or the molybdenum nitride films are obtained with the CVD process of hardly doing a thermal damage.

In addition hereto, this film has no halogen in raw materials, whereby it hardly exerts a bad influence upon the semiconductor elements. And yet, the purity of the film is high. Moreover, it is excellent in film conductivity. That is, it is preferred as a gate electrode.

And, the raw material to be employed for the present invention, particularly, the Mo raw material has a relative high vapor pressure. Accordingly, this material is easy to supply in performing the CVD process, and the film forming is easy.

### BRIEF DESCRIPTION OF THE DRAWING

This and other objects, features and advantages of the present invention will become apparent upon a reading of the following detailed description and a drawing, in which:

FIG. 1 is a schematic diagram illustrating a chemical vapor deposition (CVD) apparatus.

### DESCRIPTION OF THE EMBODIMENTS

The present invention relates to a method of forming a film containing molybdenum. Said method comprises: a Mo source supply step of supplying one or more Mo chemical compounds selected from the group of the above-mentioned general formula [I] (Additionally, in the general formula [I], in a case where R₁, R₂, R₃, R₄ or R₅ is a hydrocarbon group, a carbon number thereof is preferably 1 to 25. Moreover, a carbon number is 1 to 10. The hydrocarbon group is, particularly, an alkyl group.) as a Mo source of said film; and a decomposition step of decomposing the Mo chemical compounds supplied in said Mo source supply step. Said Mo chemical compound is, particularly, one or more chemical compounds selected from the group consisting of a biscyclopentadienylmolybdenum dihydride, a bismethylcyclopentadienylmolybdenum dihydride, a bisethylcyclopentadienylmolybdenum dihydride, and a bisisopropylcyclopentadienylmolybdenum dihydride. The present invention, particularly, relates to a method of forming a film with the CVD process. The decomposition in the CVD process is a decomposition employing at least any one of the techniques selected from the group consisting of heat, light, and a hot filament. In particularly, the present invention further comprises a reducing agent supply step of supplying a reducing agent (particularly, hydrogen).

In a case where said film is a molybdenum silicide film, the present invention further comprises: an Si source supply step of supplying SiₓH₍₂ₓ₊₂₎, where X is an integer of 1 or more, preferably, an integer of 10 or less, as an Si source of said molybdenum silicide film; and a decomposition step of decomposing the Si chemical compounds supplied in said Si source supply step. Said Si chemical compound is, particularly, one or more chemical compounds selected from the group consisting of SiH₄, Si₂H₆, and Si₃H₈. Said Mo chemical compound and said Si chemical compound are supplied simultaneously or separately. And, they are decomposed simultaneously or separately.

In a case where said film is a molybdenum nitride film, the present invention further comprises an N source supply step of supplying one or more N chemical compounds selected from the group of ammonia and ammonia producing chemical compounds (chemical compounds from which ammonia is produced by decomposition) as an N source of said molybdenum nitride film; and a decomposition step of decomposing the N chemical compounds supplied in said N source supply step. Said N chemical compound is, particularly, ammonia. Said Mo chemical compound and said N chemical compound are supplied simultaneously or separately. And, they are decomposed simultaneously or separately.

The film of the present invention is a film obtained with the above-mentioned methods.

The present invention provides a material for forming a film containing molybdenum. Said material is one or more Mo chemical compounds selected from the group of the above-mentioned general formula [I]. In particular, it is a Mo chemical compound explained in said method. Above all, the chemical compound, which most preferably configures the gate electrode, is a bisisopropylcyclopentadienylmolybdenum dihydride.

In the present invention, in a case where said film is a molybdenum silicide film, an Si source of said molybdenum silicide film is SiₓH₍₂ₓ₊₂₎, where X is an integer of 1 or more, and in addition, X is preferably an integer of 10 or less. In particular, it is an Si chemical compound explained in said method.

In the present invention, in a case where said film is a molybdenum nitride film, an N source of said molybdenum nitride film is one or more N chemical compounds selected from the group of ammonia and ammonia producing chemical compounds. In particular, it is an N chemical compound explained in said method.

The film forming material of the present invention is a material for forming a film with the CVD process. In particular, it is a material for forming a gate electrode film. In particular, it is a material for forming a gate electrode film in the semiconductor elements such as MOSFETs. Above all, it is a material for forming a molybdenum silicide film.

The semiconductor element of the present invention is a semiconductor element comprising the molybdenum film, the molybdenum silicide film, or the molybdenum nitride film. One or more Mo chemical compounds selected from the group of said general formula [I] are supplied as a Mo source, and Mo of said film is configured by decomposing said supplied Mo chemical compounds. In a case of the molybdenum silicide film, or the molybdenum nitride film, the chemical compounds mentioned before are supplied, and these films are configured by decomposing the above chemical compounds.

Specific embodiments will be described below.

### Embodiment 1

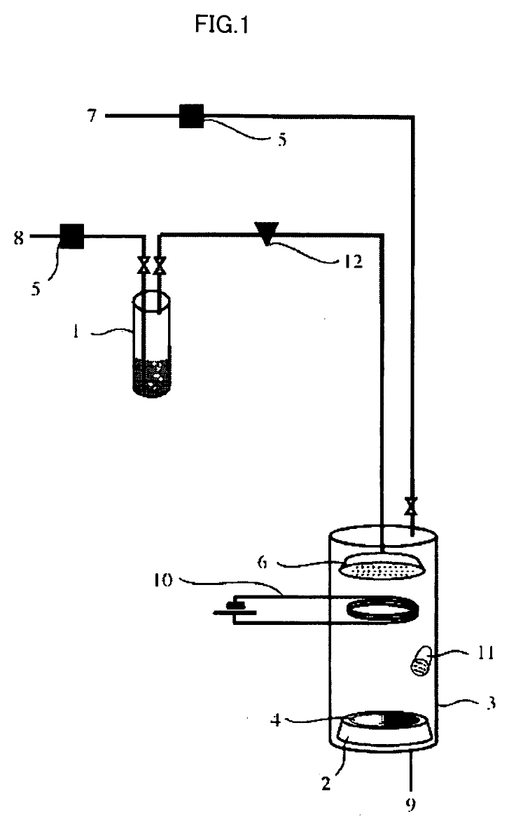

FIG. 1 is a schematic diagram illustrating a chemical vapor deposition (CVD) apparatus. In the identical figure, 1 represents a raw material container, 2 represents a heater, 3 represents a decomposition reactor, 4 represents an Si (semiconductor) substrate, 5 represents a gas flow controller, 6 represents an a gas outlet of source gas, 7 represents a leading line of silane (or ammonia) such as SiH₄, Si₂H₆ and Si₃H₈, and H₂, 8 represents a leading line of carrier gas, 9 represents an exhaust line, 10 represents a ring-shape hot filament, 11 represents a photo-irradiation device, and 12 represents a needle valve for regulating pressure within the raw material container.

A bisisopropylcyclopentadienylmolybdenum dihydride (i-PrCp₂MoH₂) was placed in the container 1, and was maintained at 120° C. The decomposition reactor 3 was evacuated in vacuum. The substrate 4 was heated at 150-450° C.

And, the needle valve 12 was released. This caused the vaporized i-PrCp₂MoH₂ to be introduced into the decomposition reactor 3.

As a result, the film was formed on the substrate 4.

This film was investigated with an XPS (X-ray photoelectron spectroscopy). As a result, existence of Mo was confirmed. Also, it was investigated with an X-ray. As a result, it was confirmed that this film was a Mo film. Also, observing SEM (Scanning Electron Microscope) photographs and TEM (Transmission Electron Microscope) photographs of the section demonstrated that an interface was extremely flat. That is, it was founded out that no reaction occurred in the interface (Si) and the excellent interface was obtained.

This film was preferred for the gate electrode of the next generation semiconductor elements.

### Embodiment 2

The embodiment 2 was carried out similarly to the embodiment 1 with the exception that a biscyclopentadienylmolybdenum dihydride was employed instead of i-PrCp₂MoH₂.

As a result, the similar Mo film was formed. This film was preferred for the gate electrode of the next generation semiconductor elements.

### Embodiment 3

The embodiment 3 was carried out similarly to the embodiment 1 with the exception that a bismethylcyclopentadienylmolybdenum dihydride was employed instead of i-PrCp₂MoH₂.

As a result, the similar Mo film was formed. This film was preferred for the gate electrode of the next generation semiconductor elements.

### Embodiment 4

The embodiment 4 was carried out similarly to the embodiment 1 with the exception that a bisethylcyclopentadienylmolybdenum dihydride was employed instead of i-PrCp₂MoH₂.

As a result, the similar Mo film was formed. This film was preferred for the gate electrode of the next generation semiconductor elements.

### Embodiment 5

The embodiment 5 was carried out similarly to the embodiment 1 with the exception that i-PrCp₂MoH₂ and SiH₄ were simultaneously introduced into the decomposition reactor 3 instead of introduction of only i-PrCp₂MoH₂.

As a result, the film was formed on the substrate 4.

This film was investigated with the XPS. As a result, Mo and Si were confirmed. Also, it was investigated with an X-ray. As a result, it was confirmed that this film was a molybdenum silicide film. Also, observing the SEM photographs and the TEM photographs of the section demonstrated that an interface was extremely flat. That is, it was founded out that no reaction occurred in the interface (Si) and the excellent interface was obtained.

This film was preferred for the gate electrode of the next generation semiconductor elements.

### Embodiment 6

The embodiment 6 was carried out similarly to the embodiment 5 with the exception that a biscyclopentadienylmolybdenum dihydride was employed instead of i-PrCp₂MoH₂.

As a result, the molybdenum silicide film similar to that of the embodiment 5 was formed. This film was preferred for the gate electrode of the next generation semiconductor elements.

### Embodiment 7

The embodiment 7 was carried out similarly to the embodiment 5 with the exception that a bismethylcyclopentadienylmolybdenum dihydride was employed instead of i-PrCp₂MoH₂.

As a result, the molybdenum silicide film similar to that of the embodiment 5 was formed. This film was preferred for the gate electrode of the next generation semiconductor elements.

### Embodiment 8

The embodiment 8 was carried out similarly to the embodiment 5 with the exception that a bisethylcyclopentadienylmolybdenum dihydride was employed instead of i-PrCp₂MoH₂.

As a result, the molybdenum silicide film similar to that of the embodiment 5 was formed. This film was preferred for the gate electrode of the next generation semiconductor elements.

### Embodiment 9

The embodiment 9 was carried out similarly to the embodiment 5 with the exception that Si₂H₆ was employed instead of SiH₄.

As a result, the molybdenum silicide film similar to that of the embodiment 5 was formed. This film was preferred for the gate electrode of the next generation semiconductor elements.

### Embodiment 10

The embodiment 10 was carried out similarly to the embodiment 5 with the exception that Si₃H₈ was employed instead of SiH₄.

As a result, the molybdenum silicide film similar to that of the embodiment 5 was formed. This film was preferred for the gate electrode of the next generation semiconductor elements.

### Embodiment 11

The embodiment 11 was carried out similarly to the embodiment 1 with the exception that i-PrCp₂MoH₂ and ammonia (NH₃) were simultaneously introduced into the decomposition reactor 3 instead of introduction of only i-PrCp₂MoH₂.

As a result, the film was formed on the substrate 4.

This film was investigated with the XPS. As a result, Mo and N were confirmed. Also, it was investigated with the X-ray. As a result, it was confirmed that this film was a molybdenum nitride film. Also, observing the SEM photographs and the TEM photographs of the section demonstrated that an interface was extremely flat. That is, it was founded out that no reaction occurred in the interface (Si) and the excellent interface was obtained.

This film was preferred for the gate electrode of the next generation semiconductor elements.

### Embodiment 12

The embodiment 12 was carried out similarly to the embodiment 11 with the exception that a biscyclopentadienylmolybdenum dihydride was employed instead of i-PrCp₂MoH₂.

As a result, the molybdenum nitride film similar to that of the embodiment 11 was formed. This film was preferred for the gate electrode of the next generation semiconductor elements.

### Embodiment 13

The embodiment 13 was carried out similarly to the embodiment 11 with the exception that a bismethylcyclopentadienylmolybdenum dihydride was employed instead of i-PrCp₂MoH₂.

As a result, the molybdenum nitride film similar to that of the embodiment 11 was formed. This film was preferred for the gate electrode of the next generation semiconductor elements.

### Embodiment 14

The embodiment 14 was carried out similarly to the embodiment 11 with the exception that a bisethylcyclopentadienylmolybdenum dihydride was employed instead of i-PrCp₂MoH₂.

As a result, the molybdenum nitride film similar to that of the embodiment 11 was formed. This film was preferred for the gate electrode of the next generation semiconductor elements.

### Embodiment 15

In the embodiment 1, the decomposition of the chemical compounds was made with the heating means.

The embodiment 15 was carried out similarly to the embodiment 1 with the exception that the photo-irradiation means was employed instead of this heating means.

As a result, the similar Mo film was formed. This film was preferred for the gate electrode of the next generation semiconductor elements.

### Embodiment 16

In the embodiment 1, the decomposition of the chemical compounds was made with the heating means.

The embodiment 16 was carried out similarly to the embodiment 1 with the exception that the laser-irradiation means was employed instead of this heating means.

As a result, the similar Mo film was formed. This film was preferred for the gate electrode of the next generation semiconductor elements.

### Embodiment 17

In the embodiment 1, the decomposition of the chemical compounds was made with the heating means.

The embodiment 17 was carried out similarly to the embodiment 1 with the exception that the decomposition was made with i-PrCp₂MoH₂ brought into contact with the hot filament 10 heated at 800° C. or more on the way to the Si substrate 4 instead of this heating means for decomposition.

As a result, the similar Mo film was formed. This film was preferred for the gate electrode of the next generation semiconductor elements.

Particularly, the present invention can be usefully applied in the semiconductor fields.

What is claimed is:

1. A method of forming a film containing molybdenum, comprising:
a Mo source supply step of supplying one or more Mo chemical compounds selected from the group of the following general formula [I] as a Mo source of said film; and
a decomposition step of decomposing the Mo chemical compounds supplied in said Mo source supply step: 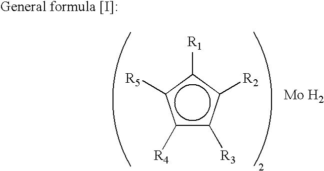
where R₁, R₂, R₃, R₄, or R₅ is H or a hydrocarbon group respectively, each which has the same type or a different type.

2. The method of forming the film as claimed in claim 1, wherein said Mo chemical compound is one or more chemical compounds selected from the group consisting of a biscyclopentadienylmolybdenum dihydride, a bismethylcyclopentadienylmolybdenum dihydride, a bisethylcyclopentadienylmolybdenum dihydride, and a bisisopropylcyclopentadienylmolybdenum dihydride.

3. The method of forming the film as claimed in claim 1, wherein said film is formed with a CVD process.

4. The method of forming the film as claimed in claim 1, wherein a gate electrode film is formed.

5. The method of forming the film as claimed in claim 1, wherein said decomposition is a decomposition employing at least any one of the techniques selected from the group consisting of heat, light, and a hot filament.

6. The method of forming the film as claimed in claim 1, further comprising a reducing agent supply step of supplying a reducing agent.

7. The method of forming the film as claimed in claim 6, wherein said reducing agent is hydrogen.

8. A method of forming a film containing Mo and Si wherein said film is a molybdenum silicide film, comprising:
a Mo source supply step of supplying one or more Mo chemical compounds selected from the group of the following general formula [I] as a Mo source of said film;
a decomposition step of decomposing the Mo chemical compounds supplied in said Mo source supply step:
an Si source supply step of supplying SiₓH₍₂ₓ₊₂₎, where X is an integer of 1 or more, as an Si source of said film; and
a decomposition step of decomposing the Si chemical compounds supplied in said Si source supply step. 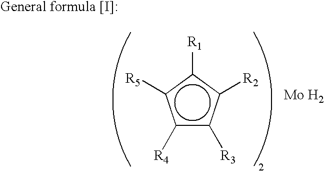
where R₁, R₂, R₃, R₄, or R₅ is H or a hydrocarbon group respectively, each which has the same type or a different type.

9. The method of forming the film as claimed in claim 8, wherein said Mo chemical compound is one or more chemical compounds selected from the group consisting of a biscyclopentadienylmolybdenum dihydride, a bismethylcyclopentadienylmolybdenum dihydride, a bisethylcyclopentadienylmolybdenum dihydride, and a bisisopropylcyclopentadienylmolybdenum dihydride.

10. The method of forming the film as claimed in claim 8, wherein said film is formed with a CVD process.

11. The method of forming the film as claimed in claim 8, wherein a gate electrode film is formed.

12. The method of forming the film as claimed in claim 8, wherein said decomposition is a decomposition employing at least any one of the techniques selected from the group consisting of heat, light, and a hot filament.

13. The method of forming the film as claimed in claim 8, further comprising a reducing agent supply step of supplying a reducing agent.

14. The method of forming the film as claimed in claim 13, wherein said reducing agent is hydrogen.

15. The method of forming the film as claimed in claim 8, wherein said Si chemical compound is one or more chemical compounds selected from the group consisting of SiH₄, Si₂H₆, and Si₃H₈.

16. The method of forming the film as claimed in claim 8, wherein film forming materials are decomposed simultaneously or separately.

17. A method of forming a film containing Mo and N wherein said film is a molybdenum nitride film comprising:
a Mo source supply step of supplying one or more Mo chemical compounds selected from the group of the following general formula [I] as a Mo source of said film;
a decomposition step of decomposing the Mo chemical compounds supplied in said Mo source supply step:
an N source supply step of supplying one or more N chemical compounds selected from the group of ammonia and ammonia producing chemical compounds as an N source of said film; and
a decomposition step of decomposing the N chemical compounds supplied in said N source supply step. 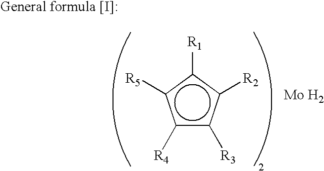
where R₁, R₂, R₃, R₄, or R₅ is H or a hydrocarbon group respectively, each which has the same type or a different type.

18. The method of forming the film as claimed in claim 17, wherein said Mo chemical compound is one or more chemical compounds selected from the group consisting of a biscyclopentadienylmolybdenum dihydride, a bismethylcyclopentadienylmolybdenum dihydride, a bisethylcyclopentadienylmolybdenum dihydride, and a bisisopropylcyclopentadienylmolybdenum dihydride.

19. The method of forming the film as claimed in claim 17, wherein said film is formed with a CVD process.

20. The method of forming the film as claimed in claim 17, wherein a gate electrode film is formed.

21. The method of forming the film as claimed in claim 17, wherein said decomposition is a decomposition employing at least any one of the techniques selected from the group consisting of heat, light, and a hot filament.

22. The method of forming the film as claimed in claim 17, further comprising a reducing agent supply step of supplying a reducing agent.

23. The method of forming the film as claimed in claim 22, wherein said reducing agent is hydrogen.

24. The method of forming the film as claimed in claim 17, wherein film forming materials are decomposed simultaneously or separately.
